(19) United States
(12) Patent Application Publication
(10) Pub. No.: US 2010/0149805 A1
(43) Pub. Date: Jun. 17, 2010

(54) LED LIGHTING LAMINATE WITH INTEGRATED COOLING

(76) Inventors: Joseph FRIDY, Pittsburgh, PA (US); Rabi BHATTACHARYYA, Export, PA (US)

Correspondence Address: INTELLECTUAL PROPERTY, ALCOA TECHNICAL CENTER, BUILDING C, 100 TECHNICAL DRIVE, ALCOA CENTER, PA, 15069-0001, US

(21) Appl. No.: 12/336,804

(22) Filed: Dec. 17, 2008

(51) Int. Cl. H01L 33/00

(52) U.S. Cl. 362/249.01; 362/249.02

(57) ABSTRACT

Light emitting diodes mounted on a tri-layer laminate with an electrically insulating middle layer sandwiched between two metallic aluminum layers. The upper aluminum layer serves as a heat sink by facilitating dissipation of heat from the light emitting diodes quicker than traditional printed circuit boards. Furthermore, fins and thermal interface material may be mounted on the backside of the laminate for added cooling.

### FIELD OF THE INVENTION

The embodiments of the present invention relate to lighting systems, more specifically, to a light emitting diode (LED) lighting system with integrated cooling.

### BACKGROUND

Lighting devices such as light emitting diodes (LED's) can be mounted on printed circuit boards (PCB's) for functional and manufacturing purposes. However, housing LED's on PCB's require photolithographic artwork and soldering connections. Furthermore, cooling the LED's can become challenging because of the poor thermal conductivity of the PCB's. As such, heat sinks may need to be mounted behind the LED's on the other side of the PCB bringing about added processing steps and cost.

### SUMMARY

Accordingly, a first embodiment discloses a laminate comprising: a first layer having an upper surface and a lower surface, the upper surface of the first layer adaptable to receive a plurality of lighting devices; a second layer having an upper surface and a lower surface, the upper surface of the second layer coupled to the lower surface of the first layer, wherein the second layer substantially insulates the first layer and the lighting devices thereon; a third layer having an upper surface and a lower surface, the upper surface of the third layer coupled to the lower surface of the second layer; and one or more apertures extending therethrough the three layers, the apertures having a sufficient design as to partition the three layers into one or more sections whereby electrical contacts can be made between the sections and the lighting devices. The lighting devices include light emitting diodes. The first and third layers can be formed of metallic materials including aluminum, gold, copper and tungsten while the second layer can be formed of electrically insulating materials including hematite, polymers and metal oxides.

The electrical contacts include metal plugs or vias and can be formed of metallic materials including gold, platinum, tungsten, aluminum and copper. The laminate further includes one or more fins coupled to the lower surface of the first layer, the fins operable to facilitate dissipation of heat from the lighting devices. Thermal interface materials may be disposed about the fins, the thermal interface material operable to facilitate dissipation of heat from the lighting devices. Thermal interface materials may also be disposed within the apertures, the thermal interface material operable to facilitate dissipation of heat from the lighting devices.

A second embodiment discloses a laminate comprising: a first layer having an upper surface and a lower surface, the upper surface of the first layer adaptable to receive a plurality of lighting devices; a second layer having an upper surface and a lower surface, the upper surface of the second layer coupled to the lower surface of the first layer, wherein the second layer substantially insulates the first layer and the lighting devices thereon; a third layer having an upper surface and a lower surface, the upper surface of the third layer coupled to the lower surface of the second layer; one or more apertures extending therethrough the three layers, the apertures having a sufficient design as to partition the three layers into one or more sections; and one or more metal contacts disposed within the apertures, the metal contacts operable to electrically couple the sections with the lighting devices. The lighting devices include light emitting diodes. The first and third layers can be formed of metallic materials including aluminum, gold, copper and tungsten while the second layer can be formed of electrically insulating materials including hematite, polymers and metal oxides.

The metal contacts can be formed of metallic materials including gold, platinum, tungsten, aluminum and copper. The apertures can be configured to expose the lower surface of the first layer. The laminate further includes one or more fins coupled to the lower surface of the first layer, the fins operable to facilitate dissipation of heat from the lighting devices. Thermal interface materials may be disposed about the fins, the thermal interface material operable to facilitate dissipation of heat from the lighting devices. Thermal interface materials may also be disposed within the apertures, the thermal interface material operable to facilitate dissipation of heat from the lighting devices.

A third embodiment discloses a laminate comprising: a top layer having an upper surface and a lower surface, the upper surface of the top layer adaptable to receive a plurality of light emitting diodes; a middle layer having an upper surface and a lower surface, the upper surface of the middle layer coupled to the lower surface of the top layer, wherein the middle layer substantially insulates the top layer and the light emitting diodes thereon from electrical activities and ambient elements; a bottom layer having an upper surface and a lower surface, the upper surface of the bottom layer coupled to the lower surface of the middle layer; one or more apertures extending therethrough the three layers, the apertures having a sufficient design as to partition the three layers into one or more sections, wherein a portion of the lower surface of the top layer remain exposed and in contact with the light emitting diodes; and one or more metal contacts disposed within the apertures, the metal contacts operable to electrically couple the sections with the light emitting diodes, and wherein the metal contacts can be formed of metallic materials including gold, platinum, tungsten, aluminum and copper.

The top layer, bottom layer and contacts can be formed of metallic materials including aluminum, gold, copper and tungsten, while the middle layer can be formed of electrically insulating materials including hematite, polymers and metal oxides. The laminate further includes one or more fins coupled to the exposed lower surface of the top layer, the fins operable to facilitate dissipation of heat from the light emitting diodes. Thermal interface materials may be disposed about the fins, the thermal interface material operable to facilitate dissipation of heat from the light emitting diodes. Thermal interface materials may also be disposed within the apertures, the thermal interface material operable to facilitate dissipation of heat from the light emitting diodes.

Other variations, embodiments and features of the present invention will become evident from the following detailed description, drawings and claims.

### BRIEF DESCRIPTION OF THE DRAWINGS

FIG. 1 illustrates a cross-sectional view of a first embodiment of a light emitting diode (LED) laminate;

FIG. 2 illustrates a top perspective view of the laminate having a series configuration;

FIG. 3 illustrates a bottom perspective view of the laminate;

FIG. 4 illustrates a close-up view of the laminate;

FIG. 5 illustrates a top perspective view of the laminate having a parallel configuration;

FIG. 6 illustrates a bottom perspective view of the laminate; and

FIG. 7 illustrates a close-up view of the laminate.

### DETAILED DESCRIPTION

It will be appreciated by those of ordinary skill in the art that the invention can be embodied in other specific forms without departing from the spirit or essential character thereof. The presently disclosed embodiments are therefore considered in all respects to be illustrative and not restrictive.

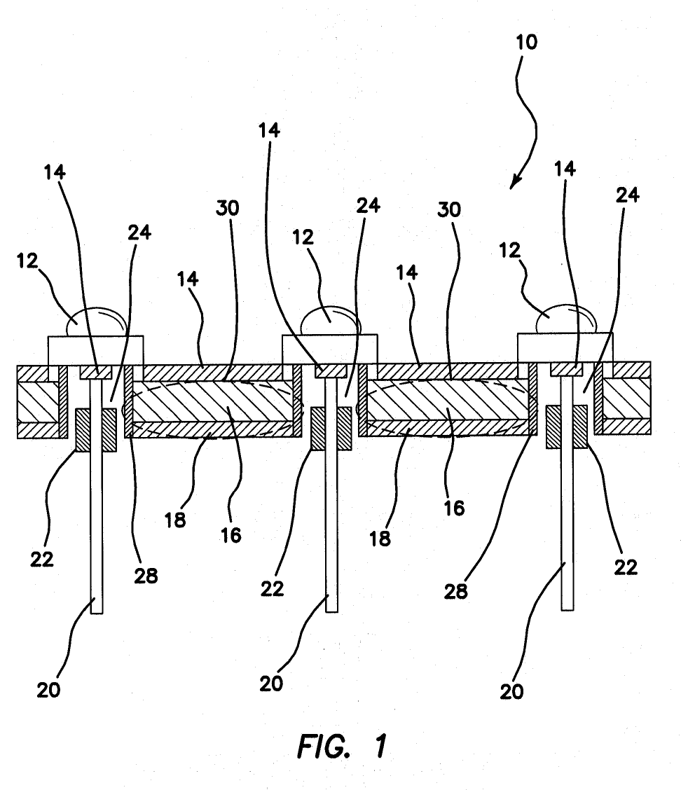

FIG. 1 illustrates a cross-sectional view of a laminate 10 according to a first embodiment of the present invention. The laminate 10 has an electrically insulating middle layer 16 coupled between two electrically conductive layers 14, 18. The electrically insulating layer 16 can be formed of hematite, polymer and metal oxide while the electrically conductive layers 14, 18 can be formed of aluminum, gold, platinum, tungsten, copper and other metallic materials. In other embodiments, the layers 14, 16, 18 can also incorporate composite materials. In this embodiment, the electrically insulating layer 16 binds the upper and lower aluminum layers 14, 18 to form the multi-layered laminate 10. In other embodiments, mechanical fasteners and adhesives may be utilized for coupling the tri-layer laminate 10. As shown in the figure, a plurality of lighting devices 12 including light emitting diodes (LED's) may be disposed about the upper surface of the top aluminum layer 14. In one instance, the insulating layer 16 is capable of protecting the layers 14, 18 and the lighting devices 12 within the laminate 10 from heat, cold, noise or electricity. In another instance, the insulating layer 16 facilitates in separating, detaching or isolating the electrically conductive layers 14, 18 and the lighting devices 12 from other objects within the laminate 10. In other embodiments, the lighting devices may include semiconductor and solid-state devices capable of emitting visible light or invisible infrared radiation.

The laminate 10 also includes one or more openings or apertures 24 formed within the middle and bottom layers 16, 18 exposing the underside of the upper aluminum layer 14. In some portions of the laminate 10 the apertures 24 may extend through the top layer 14 allowing direct electrical and thermal contacts to be made with the lighting devices 12 thereon. In one example, the apertures 24 are openings or holes formed within the layers 14, 16, 18 not limited by any shapes or sizes. The openings 24 may be formed by boring, drilling, milling, punching, blanking, and other mechanical or chemical etching processes. Once formed, the apertures 24 partition the layers 14, 16, 18 into disjoint patches 30 (best illustrated in FIGS. 3 and 6), with each patch 30 being electrically isolated from one another and from the upper electrically conductive layer 14. The shapes and sizes of these patches 30 can be arbitrary. For example, the apertures 24 can define rectangular and square patches 30 as shown in FIGS. 3 and 6, respectively. In other instances, the apertures 24 can define patches with hexagonal and polygonal shapes (not shown).

Returning now to FIG. 1, the patches 30 can be electrically connected to the LED's 12 via known bonding techniques including soldering, welding and the use of other mechanical fasteners. In this instance, the patches 30 are electrically and thermally coupled to the LED's 12 via a plurality of vias or contacts 28 within apertures 24 extending through the three layers 14, 16, 18. In this embodiment, the contacts or vias 28 can be formed of metallic materials including gold, platinum, tungsten, aluminum and copper. In one instance, the contacts 28 are metal plugs or vias capable of conducting electricity and/or heat. Other electrically conductive materials may also be incorporated in the vias or contacts 28, which can be formed by known fabrication methods including electroplating and other deposition techniques. Despite the metal contacts 28, the patches 30 are still electrically isolated from each other and the upper aluminum layer 14.

In one embodiment, the upper layer 14 of the laminate 10 can provide the mechanical backing by supporting the plurality of lighting devices 12 thereon. Additionally, the aluminum layer 14 can function as a reflecting surface because of its material properties. Furthermore, the upper aluminum layer 14 can serve as a heat sink for the lighting devices 12 by facilitating the dissipation of heat generated or built up due to operation of the LED's 12.

In other embodiments, fins 20 may be attached to the backside of the upper aluminum layer 14 to further facilitate thermal dissipation of the LED's 12. The fins 20 can be formed of metallic materials including aluminum, gold, tungsten or copper and be disposed about the backside of the upper layer 14 using known deposition techniques similar to those described above. In this embodiment, the fins 20 are coupled to the underside of the top layer 14 that were not etched or removed when the apertures 24 were formed. Furthermore, a thermal interface material (TIM) 22 may be disposed about the fins 20 to facilitate further heat dissipation from the LED's 12. In other words, the TIM 22 can be used to fill any gaps or spaces surrounding the fins 20 and the apertures 24 to provide more intimate, direct contact with the LED's 12. Furthermore, although fins 20 are provided, they may not be necessary and any remaining gaps or spaces surrounding the grooves or apertures 24 may be filled with thermal interface materials (TIM's) after the metal contacts have been formed 28 within the apertures 24. The TIM's are able to protect the lighting devices 12 from ambient elements including the likes of electricity, water, heat, humidity and inadvertent physical touching or damage. In some instances, the TIM's may also facilitate the dissipation of heat generated by the plurality of LED's 12.

As shown in FIG. 1, the LED's 12 are mounted to the top surface 14 of the laminate 10 such that the backside of the LED 12 bridges or centers about the groove or aperture 24. Doing so allows the anode of the LED 12 to be electrically connected to an aluminum patch 30 on one side of the aperture 24 while the cathode of the LED 12 can be electrically connected to another aluminum patch 30 on the other side of the aperture 24. In other words, using the center LED 12 of the figure as an example, the anode of this LED 12 can be coupled to the patch 30 on the right side of the LED 12 while the cathode of this LED 12 can be coupled to the patch 30 on the left side of the LED 12. Accordingly, arbitrary series and parallel arrangements of LED's can be accommodated by appropriately bridges the patches 30.

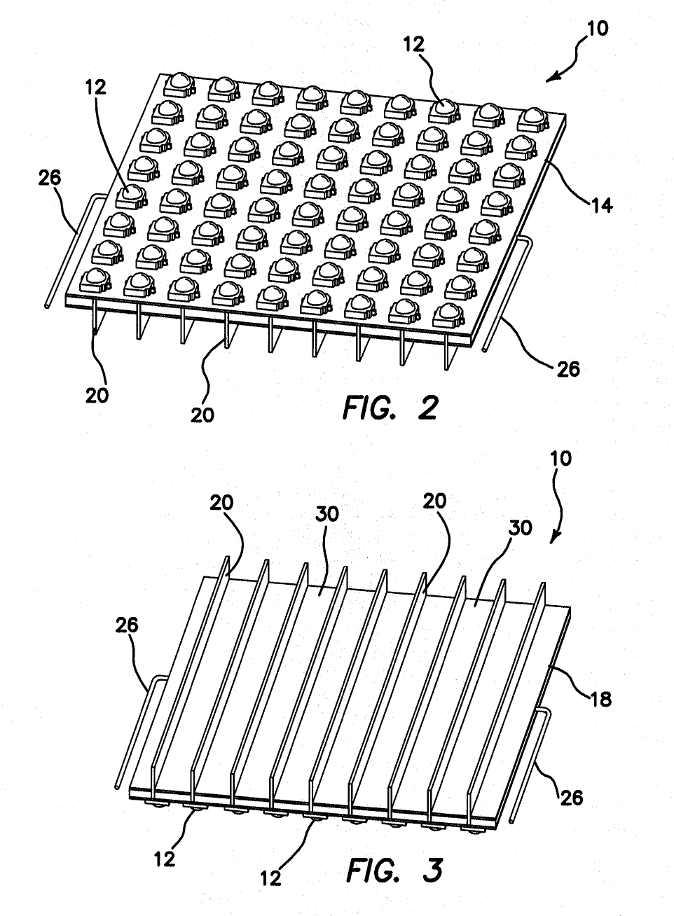

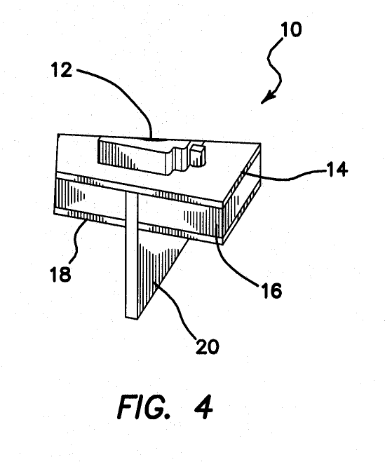

Reference is now made to FIGS. 2-3 illustrating top and bottom perspective views of the laminate 10 having a series configuration and FIG. 4 illustrating a close-up perspective view of the laminate 10. In these figures, the LED lighting devices 12 can be coupled to the top electrically conductive aluminum layer 14 while a plurality of fins 20 can be coupled to the underside of the upper layer 14 centered about the LED's 12 as previously discussed and best illustrated in FIG. 4. The laminate 10 further includes the middle electrically insulating layer 16 and the bottom aluminum layer 18. In these figures, a plurality of rectangular patches 30 can be formed running the length of the laminate 10. These patches 30 can be configured to provide alternating strips of cathode and anode and be coupled to external devices. As shown, electrical outlets 26 may be provided near the ends of the patches 30 to facilitate electrical connections to a power source such as a battery or wall outlet in powering the plurality of LED's 12.

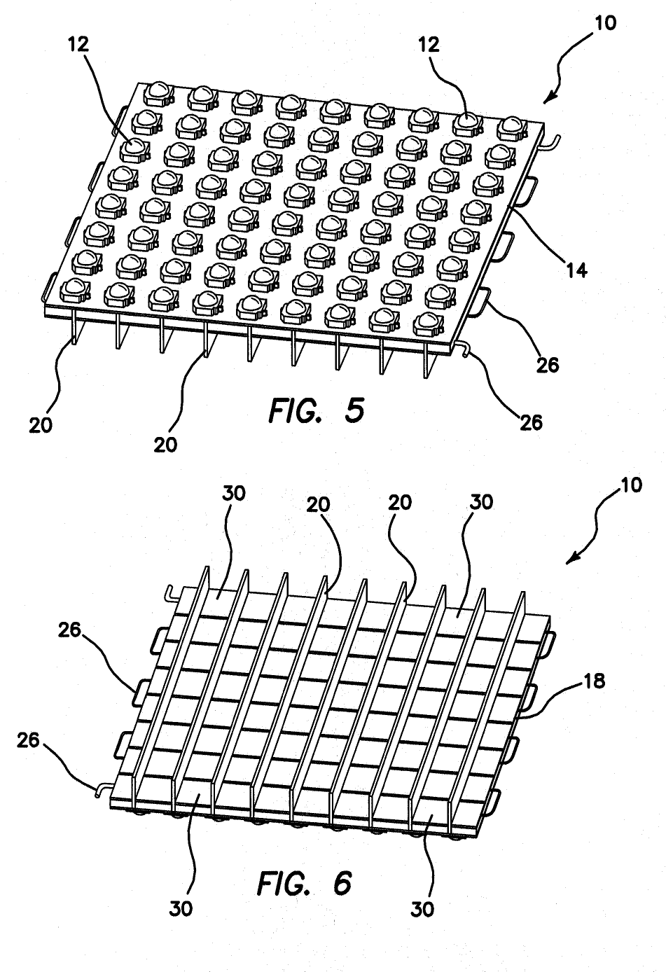

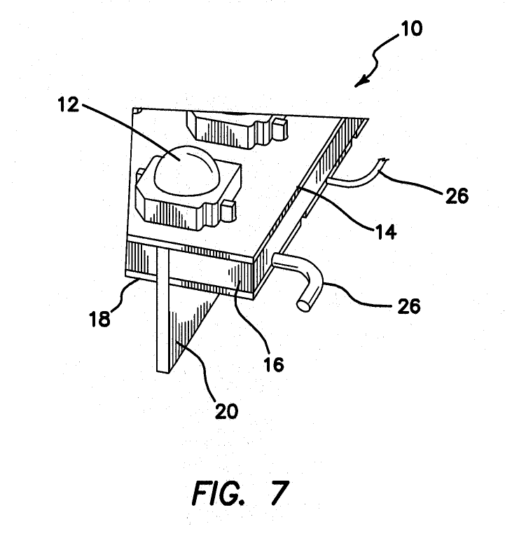

Reference is now made to FIGS. 5-6 illustrating top and bottom perspective views of the laminate 10 having a parallel configuration and FIG. 7 illustrating a close-up perspective view of the laminate 10. Like above, the LED lighting devices 12 can be coupled to the upper electrically conductive layer 14 while a plurality of fins 20 can be coupled to the underside of the upper layer 14 centered about the LED's 12 as previously discussed and best illustrated in FIG. 7. The laminate 10 further includes the center electrically insulating layer 16 and the lower electrically conductive layer 18. Unlike above, however, the plurality of square patches 30 formed provide alternating blocks of cathode and anode for coupling to external devices. In other words, additional electrical outlets 26 are needed to bridge alternating or parallel electrical connections. In this embodiment, multiple electrical outlets 26 may be necessary and can be embedded within the middle or bottom layers 16, 18 of the laminate 10 as best shown in FIG. 7. Like above, the apertures 24 of the laminate 10 can be filled with TIM's for enhanced heat dispersion.

In these embodiments, the LED's 12 are connected to a more thermally conductive substrate, i.e., the electrically conductive top layer 14 formed of metallic materials such as aluminum and gold. This thermally conductive layer 14 can better dissipate or disperse heat away from the LED's 12 than traditional PCB's. Furthermore, cooling fins 20 may be attached much closer to the LED's 12, i.e., on the underside, than previous technologies. Last but not least, the grooved laminate 10 is capable of accommodating a large number of layouts without requiring a change in the laminate material 10 and still allow efficient cooling of the LED's 12. The laminate 10 can be formed into a non-planar contour and the LED's 12 may be mounted to that contour and still provide the needed cooling effects. In doing so, the artwork and the photolithography necessary for mounting LED's 12 to PCB's are consequently eliminated. In some instances, the PCB may also no longer be necessary. Furthermore, because the laminates 10 can be provided in much larger sheets than traditional PCB's, any size restrictions due to photolithography can be eliminated.

Although the invention has been described in detail with reference to several embodiments, additional variations and modifications exist within the scope and spirit of the invention as described and defined in the following claims.

What is claimed is:

1. A laminate comprising:
a first layer having an upper surface and a lower surface, the upper surface of the first layer adaptable to receive a plurality of lighting devices;
a second layer having an upper surface and a lower surface, the upper surface of the second layer coupled to the lower surface of the first layer, wherein the second layer substantially insulates the first layer and the lighting devices thereon;
a third layer having an upper surface and a lower surface, the upper surface of the third layer coupled to the lower surface of the second layer; and
one or more apertures extending therethrough the three layers, the apertures having a sufficient design as to partition the three layers into one or more sections whereby electrical contacts can be made between the sections and the lighting devices.

2. The laminate of claim 1, wherein the lighting devices include light emitting diodes.

3. The laminate of claim 1, wherein the first and third layers can be formed of metallic materials including aluminum, gold, copper and tungsten while the second layer can be formed of electrically insulating materials including hematite, polymers and metal oxides.

4. The laminate of claim 1, wherein the electrical contacts are metal plugs or vias and can be formed of metallic materials including gold, platinum, tungsten, aluminum and copper.

5. The laminate of claim 4, further comprising one or more fins coupled to the lower surface of the first layer, the fins operable to facilitate dissipation of heat from the lighting devices.

6. The laminate of claim 5, further comprising thermal interface materials disposed about the fins, the thermal interface material operable to facilitate dissipation of heat from the lighting devices.

7. The laminate of claim 1, further comprising thermal interface materials disposed within the apertures, the thermal interface material operable to facilitate dissipation of heat from the lighting devices.

8. A laminate comprising:
a first layer having an upper surface and a lower surface, the upper surface of the first layer adaptable to receive a plurality of lighting devices;
a second layer having an upper surface and a lower surface, the upper surface of the second layer coupled to the lower surface of the first layer, wherein the second layer substantially insulates the first layer and the lighting devices thereon;
a third layer having an upper surface and a lower surface, the upper surface of the third layer coupled to the lower surface of the second layer;
one or more apertures extending therethrough the three layers, the apertures having a sufficient design as to partition the three layers into one or more sections; and
one or more metal contacts disposed within the apertures, the metal contacts operable to electrically couple the sections with the lighting devices.

9. The laminate of claim 8, wherein the lighting devices include light emitting diodes.

10. The laminate of claim 8, wherein the first and third layers can be formed of metallic materials including aluminum, gold, copper and tungsten while the second layer can be formed of electrically insulating materials including hematite, polymers and metal oxides.

11. The laminate of claim 8, wherein the metal contacts can be formed of metallic materials including gold, platinum, tungsten, aluminum and copper.

12. The laminate of claim 8, wherein the apertures are configured to expose the lower surface of the first layer.

13. The laminate of claim 12, further comprising one or more fins coupled to the lower surface of the first layer, the fins operable to facilitate dissipation of heat from the lighting devices.

14. The laminate of claim 13, further comprising thermal interface materials disposed about the fins, the thermal interface material operable to facilitate dissipation of heat from the lighting devices.

15. The laminate of claim 8, further comprising thermal interface materials disposed within the apertures, the thermal interface material operable to facilitate dissipation of heat from the lighting devices.

16. A laminate comprising:
a top layer having an upper surface and a lower surface, the upper surface of the top layer adaptable to receive a plurality of light emitting diodes;
a middle layer having an upper surface and a lower surface, the upper surface of the middle layer coupled to the lower surface of the top layer, wherein the middle layer substantially insulates the top layer and the light emitting diodes thereon from electrical activities and ambient elements;
a bottom layer having an upper surface and a lower surface, the upper surface of the bottom layer coupled to the lower surface of the middle layer;
one or more apertures extending therethrough the three layers, the apertures having a sufficient design as to partition the three layers into one or more sections, wherein a portion of the lower surface of the top layer remain exposed and in contact with the light emitting diodes; and
one or more metal contacts disposed within the apertures, the metal contacts operable to electrically couple the sections with the light emitting diodes, and wherein the metal contacts can be formed of metallic materials including gold, platinum, tungsten, aluminum and copper.

17. The laminate of claim 16, wherein the top layer, bottom layer and contacts can be formed of metallic materials including aluminum, gold, copper and tungsten, while the middle layer can be formed of electrically insulating materials including hematite, polymers and metal oxides.

18. The laminate of claim 16, further comprising one or more fins coupled to the exposed lower surface of the top layer, the fins operable to facilitate dissipation of heat from the light emitting diodes.

19. The laminate of claim 18, further comprising thermal interface materials disposed about the fins, the thermal interface material operable to facilitate dissipation of heat from the light emitting diodes.

20. The laminate of claim 16, further comprising thermal interface materials disposed within the apertures, the thermal interface material operable to facilitate dissipation of heat from the light emitting diodes.
